(19) United States
(12) Patent Application Publication
(10) Pub. No.: US 2026/0062803 A1
(43) Pub. Date: Mar. 5, 2026

(54) SEMICONDUCTOR PROCESSING SYSTEMS AND ASSOCIATED METHODS FOR FORMING SUPER-LATTICE STRUCTURES USING SEMICONDUCTOR PROCESSING SYSTEMS

(71) Applicant: ASM IP Holding B. V., Almere (NL)

(72) Inventors: Fan Gao, Chandler, AZ (US); Junwei Su, Chandler, AZ (US); Mingyang Ma, Phoenix, AZ (US); Wentao Wang, Chandler, AZ (US); Krishnaswamy Mahadevan, Tempe, AZ (US); Kishor Patil, Chandler, AZ (US)

(21) Appl. No.: 19/313,558

(22) Filed: Aug. 28, 2025

Related U.S. Application Data
(60) Provisional application No. 63/689,111, filed on Aug. 30, 2024.

(51) Int. Cl. C23C 16/455; C23C 16/44; C23C 16/48; C23C 16/52; H01J 37/32

(52) U.S. Cl. CPC C23C 16/45514; C23C 16/4412; C23C 16/45502; C23C 16/482; C23C 16/52; H01J 37/32357; H01J 37/32449; H01J 2237/3321

(57) ABSTRACT

Methods and apparatuses for a material layer deposition method in a semiconductor manufacturing system. A controller may seat a substrate on a substrate support. A first vapor phase reactant may be provided to a first inlet, and a second vapor phase reactant may be provided to a remote plasma unit, which may decompose at least a portion of the precursor. An epitaxial material layer comprising silicon may be deposited onto the substrate using a decomposition product.

### CROSS-REFERENCE TO RELATED APPLICATION(S)

This application claims the benefit of U.S. Provisional Application 63/689,111 filed on Aug. 30, 2024, the entire contents of which are incorporated herein by reference.

### FIELD

The present disclosure generally relates to deposition methods and systems. More particularly, the disclosure relates to semiconductor manufacturing systems configured for performing plasma enhanced epitaxial deposition processes.

### BACKGROUND

In plasma enhanced chemical vapor deposition, an epitaxial layer (e.g., a material layer) can be deposited on a substrate, such as a silicon wafer. After the generation of excited species by a plasma generation device, chemical reactions may occur in a reaction chamber, where one or more reactants may react and/or decompose on the substrate surface to produce the material layer.

To facilitate the occurrence of the chemical reactions, conventional systems may attempt to increase the temperature at which the deposition occurs. However, such approaches may require large energy consumption and/or exceed the thermal budget of certain semiconductor materials on the substrate, thereby causing undesirable effects such as instability and chamber coating. As a result, conventional systems may lack a mechanism to strike a balance between growth rate and thermal consumption, and thereby limit their ability to control precursor deposition and provide optimal performance, throughput, and energy consumption in the semiconductor manufacturing process.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments provided include a semiconductor processing system comprising: a chamber body having an upper wall and a lower wall, wherein the upper wall extends longitudinally between an injection end and a longitudinally opposite exhaust end, and the lower wall is below and parallel relative to the upper wall; a substrate support configured to support a substrate and arranged within an interior of the chamber body between the injection end and the exhaust end; a first inlet coupled to the chamber body and configured for introducing a first vapor phase reactant into the chamber body; a second inlet coupled to the chamber body and separated from the first inlet; the second inlet configured for introducing a plasma generated reactant into the chamber body; a remote plasma unit having a plasma outlet coupled to the second inlet and configured to generate the plasma generated reactant by the decomposition of a second vapor phase reactant; and an isolating member positioned between the first inlet and the second inlet and configured to isolate the first vapor phase reactant from the plasma generated reactant until the first vapor phase reactant and plasma generated reactant are proximate to the substrate support.

In some embodiments the first inlet comprises an injection flange connected to the injection end of the chamber body.

In some embodiments the injection flange comprises a plurality of injection ports disposed in a front face of the injection flange, and a plurality of flow controllers configured to control a flow of the first vapor phase reactant from a precursor source to the plurality of injection ports and therethrough to the interior of the chamber body.

In some embodiments the second inlet is positioned between the injection flange and the substrate support.

In some embodiments the second inlet is disposed in the lower wall of the chamber body.

In some embodiments the isolating member extends into the interior of the chamber body from the injection flange toward the substrate support.

In some embodiments the isolating member comprises an opaque material.

In some embodiments the isolating member is positioned a vertical distance above the substrate support.

In some embodiments the isolating member is angled toward the substrate support.

In some embodiments the precursor source includes a silicon precursor in fluid communication with a precursor inlet of the remote plasma unit and the plasma generated reactant comprises a plurality of energetic silicon species.

In some embodiments the remote plasma unit comprises an inductively coupled plasma source or a microwave plasma source.

In some embodiments the semiconductor processing system further comprising an exhaust flange connected to the exhaust end of the chamber body and a vacuum pump coupled to the exhaust flange and therethrough to the remote plasma unit.

In some embodiments the chamber body has a plurality of external ribs extending laterally about an exterior of the chamber body and longitudinally spaced apart from one another between the injection end and the longitudinally opposite the exhaust end of the chamber body.

In some embodiments the semiconductor processing system further comprising a heater element array supported outside of the chamber body and optically coupled to the substrate support and the isolating member, the heater element array comprising: a plurality of lower linear lamps supported below the chamber body and optically coupled to the substrate support and the isolating member by a quartz material forming the chamber body; and a plurality of upper linear lamps supported above the chamber body and optically coupled to the substrate support and the isolating member by the quartz material forming the chamber body.

In some embodiments the semiconductor processing system further comprising a controller including a processor and memory having instructions recorded on the memory that, when read by the processor, cause the processor to: seat the substrate on the substrate support; provide a germanium precursor to the injection flange; provide the silicon precursor to the remote plasma unit; decompose at least a portion of the silicon precursor using the remote plasma unit to generate the plasma generated reactant; and deposit one or more epitaxial silicon-containing layers onto the substrate by combining the germanium precursor with the plasma generated reactant created using the decomposition product generated from the silicon precursor; wherein the deposition of the one or more epitaxial silicon-containing layers is an isothermal deposition process.

Various embodiments provided include a method for forming a super-lattice structure on a substrate comprising: at a chamber body having an upper wall and a lower wall, wherein the upper wall extends longitudinally between an injection end and a longitudinally opposite exhaust end, and the lower wall is below and parallel relative to the upper wall; epitaxially depositing a super-lattice structure on the substrate supported on a substrate support disposed within an interior of the chamber body between the injection end and the exhaust end, wherein the super-lattice structure comprises two or repeated unit bilayers, each unit bilayer comprising an epitaxial silicon layer and an adjoining epitaxial silicon germanium layer; and wherein depositing each unit bilayer of the super-lattice structure comprises performing two or more epitaxial deposition super cycles, each deposition super cycle comprising: depositing an epitaxial silicon layer by performing a first epitaxial deposition process comprising: introducing a plasma generated reactant into the chamber body through a second inlet coupled to the chamber body and separate from a first inlet, wherein the plasma generated reactant is generated by introducing a second vapor phase reactant comprising a silicon precursor to a remote plasma unit configured for generating the plasma generated reactant; and depositing an epitaxial silicon germanium layer on the epitaxial silicon layer by performing a second epitaxial deposition process comprising: introducing a first vapor phase reactant comprising a germanium precursor into the chamber body through the first inlet coupled to the chamber body; introducing the plasma generated reactant into the chamber body through the second inlet coupled to the chamber body and separate from the first inlet, wherein the plasma generated reactant is generated by introducing the second vapor phase reactant comprising the silicon precursor to the remote plasma unit configured for generating the plasma generated reactant; and isolating the first vapor phase reactant and the plasma generated reactant from one another until the first vapor phase reactant and the plasma generated reactant are proximate to the substrate support by employing an isolating member positioned between the first inlet and the second inlet.

In some embodiments epitaxially depositing the super-lattice structure comprises an isothermal epitaxial deposition process.

In some embodiments the first inlet comprises an injection flange connected to the injection end of the chamber body, the injection flange comprising a plurality of injection ports disposed in a front face of the injection flange, and a plurality of flow controllers configured to control a flow of the first vapor phase reactant from a precursor source to the plurality of injection ports and therethrough to the interior of the chamber body.

In some embodiments the second inlet is disposed in the lower wall of the chamber body between the injection flange and the substrate support.

In some embodiments the isolating member comprises an opaque material.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates is a schematic view of a semiconductor processing system in accordance with the one or more embodiments of the disclosure.

FIG. 2 illustrates a cross-sectional view of a chamber arrangement in accordance with one or more embodiments of the disclosure.

FIG. 3 illustrates a plan view of a chamber arrangement in accordance with one or more embodiments of the disclosure.

FIG. 4 illustrates an exemplary process in accordance with one or more embodiments of the disclosure.

FIG. 5 illustrates an exemplary process for forming a super-lattice structure in accordance with one or more embodiments of the disclosure.

FIG. 6 illustrates exemplary sub-processes for forming a super-lattice structure in accordance with one or more embodiments of the disclosure.

FIG. 7 depicts an example of a computing device that may be used in implementing one or more aspects of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Various embodiments provided relate to epitaxial deposition methods and semiconductor processing systems, such as plasma enhanced epitaxial chemical vapor system, for example. The semiconductor processing systems may be used to process substrates, such as semiconductor wafers. By way of examples, the systems described herein can be used to form or grow epitaxial layers (e.g., two component and/or doped semiconductor layers) on a surface of a substrate.

Various embodiments of the disclosure provide semiconductor processing system and methods for the deposition of super-lattice structures comprising alternating epitaxial layers, such as, for example, alternating epitaxial layers of silicon and silicon germanium (Si/SiₓGe₁₋ₓ). The exemplary semiconductor processing systems provided can enable the deposition of super-lattice structures by isothermal epitaxial deposition methods thereby allowing for all component layers of the super-lattice structure to be deposited at the same temperature, or substantially the same temperature. The ability to perform isothermal super-lattice epitaxial deposition processes in the semiconductor processing systems provided is at least partially enabled as a result of employing two separate reactant inlets into the chamber body in which the substrate is supported. The two reactant inlets can be configured such that a first inlet introduces vapor phase reactants into the chamber body and a separate second inlet introduces plasma generated reactants into the chamber body. The first inlet and the second inlet and their associated reactants are further separated by an isolating member positioned between the first inlet and the second inlet. For example, the isolating member can maintain spatial separation between the vapor phase reactants (i.e., from the first inlet) and the plasma generated reactants (i.e., from the second inlet) within the chamber interior until both reactants are proximate to, adjacent to, or in contact with the substrate support upon which the substrate is seated. Maintaining spatial separation between the vapor phase reactants and the plasma generated reactants by both physical separation of the first and second inlets in conjunction with the internal (i.e., in-situ) isolating member prevents, or least substantially prevents, premature reactions and reaction by-products from forming until proximate to the heated substrate on which deposition of the super-lattice structure is desired.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

The terms precursor gas and/or precursor gasses may refer to a gas or combination of gasses that participate in a chemical reaction that produces another compound. For example, precursor gasses may be used to grow an epitaxial layer comprising silicon germanium. Precursor gasses may include a deposition gas or gasses, a dopant gas or gasses, or a combination of a deposition gas or gasses and a dopant gas or gasses. The precursor gases may include a silicon precursor such as a high-order silicon precursor. The silicon precursor may further include silane (SiH₄) or chlorosilane (SiCl₄). In some examples, the high-order silicon precursor may have one silicon atom per molecules, such as silane. The high-order silicon precursor may have two or more silicon atoms per molecules, such as disilane. In some examples, the high-order silicon precursors may have three or more silicon atoms. The high-order silicon precursors may include a non-halogenated high-order silicon precursor, such as trisilane and tetrasilane. The high-order silicon precursor may include a halogenated high-order silicon precursor, for example, a high-order chlorine-containing precursors, such as chlorodisilane, dichlorosilane, trichlorosilane, and tetrachloridesilane. The precursor gases may include a high-order germanium-containing material layer precursor, such as germane, digermane, trigermane, their chloride derivatives and mixtures thereof. The precursor gases may include a P-dopant high order precursor such as diborane (B₂H₆). The precursor gases may also include an N-dopant high order precursor such as phosphine (PH₃) and arsine (AsH₃).

As used herein, the term “epitaxial layer” can refer to a substantially single crystalline layer directly on an underlying substantially single crystalline substrate or layer.

As used herein, the term “chemical vapor deposition” can refer to any process wherein a substrate is exposed to one or more volatile precursors/reactants (as well as optional additional process gases), which react and/or decompose on a substrate surface to produce a desired deposition.

As used here, the term “silicon germanium” can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein. In addition, the term “silicon germanium” can be represented as SiGe and can further be represented as SiGe:B when said silicon germanium is doped with a boron dopant. Likewise, a silicon material doped with a boron dopant can be represented as Si:B.

In the following description of the various embodiments, reference is made to the accompanying drawings, which form a part hereof, and in which is shown by way of illustration various embodiments in which aspects of the disclosure may be practiced. It is to be understood that other embodiments may be utilized, and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

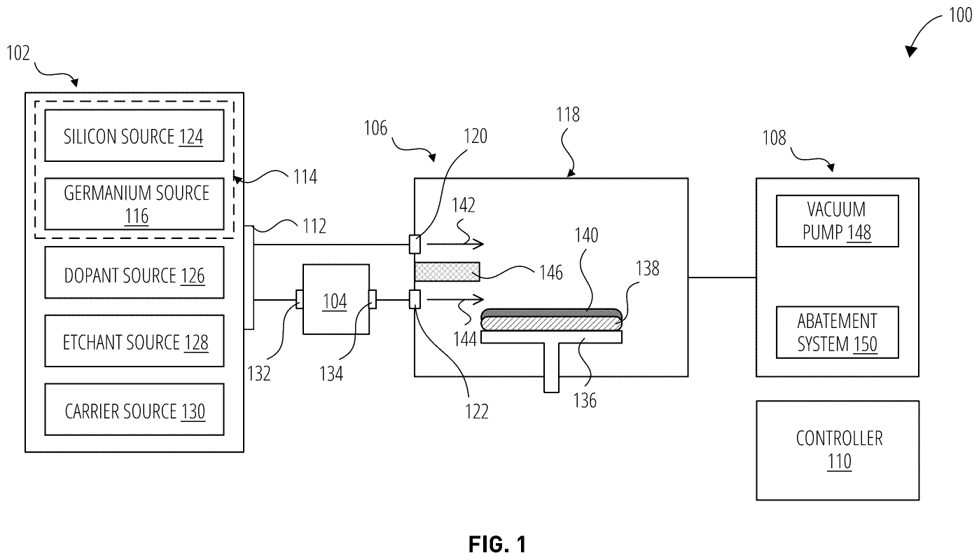

FIG. 1 illustrates a semiconductor processing system 100. In accordance with examples of the disclosure, the semiconductor processing system 100 can include a gas source assembly 102, a remote plasma unit 104, a chamber arrangement 106, an exhaust assembly 108, and a controller 110.

The gas source assembly 102 is constructed and arranged to provide a process gas to the chamber arrangement 106. The process gas can comprise one or more vapor phase reactants either as a singular gas or a mix of gases including, but not limited to, precursor gases, dopant gases, etchant gases, and inert gases (e.g., purge gases, carrier gases). The gas source assembly 102 can include various systems and components (not illustrated) for generating and controlling the flow of the one or more vapor phase reactants, from the sources included therein, to the process gas output 112 of the gas source assembly 102 and onto the chamber arrangement 106. For example, the gas source assembly 102 can include a precursor source 114 which can comprise a number of precursor sources for supplying vapor phase reactants to the chamber arrangement 106 and/or to the remote plasma unit 104. In some embodiments the precursor source 114 comprises a silicon source including one or more silicon precursors and a germanium source 116 including one or more germanium precursors.

In accordance with examples of the disclosure, the gas source assembly 102 can be configured to provide a first vapor phase reactant to the chamber arrangement 106 from the precursor source 114. In such examples the first vapor phase reactant may comprise one or more precursors, as well as additional gases such as, dopants, etchants, carrier gases, and the like. In such embodiments the first vapor phase reactant is supplied to the chamber arrangement 106 where it is introduced into the chamber body 118 in vapor form by a first inlet 120.

In some embodiments the gas source assembly 102 can be configured to provide a second vapor phase reactant to the remote plasma unit 104 from the precursor source 114. In such embodiments the remote plasma unit 104 can be employed to generate a plasma generated reactant by excitation of the second vapor phase reactant. The plasma generated reactant can in turn be provided to the chamber arrangement 106. In such examples the second vapor phase reactant may comprise one or more precursors, as well as additional gases such as, dopants, etchants, carrier gases, and the like. In a particular example the second vapor phase reactant may comprise a silicon precursor. In various embodiments the second vapor phase reactant is supplied to the remote plasma unit 104 in which a plasma generated reactant is generated and which is subsequently introduced into the chamber body 118 by a second inlet 122.

The precursor source 114 component of the gas source assembly 102 may comprise a silicon source 124. The silicon source 124 is a structure that provides a flow of a silicon precursor (not shown in FIG. 1) to the chamber arrangement 106 and/or the remote plasma unit 104. The silicon source 124 may be connected to the remote plasma unit 104 via flow controllers (not illustrated in FIG. 1), and may deliver a silicon precursor to the remote plasma unit 104. The silicon source 124 may be further configured to provide a flow of the silicon precursor to the chamber arrangement 106 either directly and/or via the remote plasma unit 104.

In some embodiments the silicon source 124 may include a silicon precursor having one silicon atom per molecule such as silane (SiH₄) or monochlorosilane (ClH₃Si). Alternatively (or additionally), the silicon precursor may include a high-order silicon precursor such as a silicon precursor having two or more silicon atoms per molecule, or three or more silicon atoms in certain examples. The high-order silicon precursors may include a non-halogenated high-order silicon precursor, such as trisilane and tetrasilane. The high-order silicon precursor may include a halogenated high-order silicon precursor, for example, a high-order chlorine-containing precursors, such as chlorodisilane, dichlorosilane, trichlorosilane, and tetrachloridesilane.

In some embodiments the silicon source 124 can comprise a silane and/or a halosilane. In some embodiments, the silicon precursor can include a hydrogenated silicon precursor. In such embodiments the hydrogenated silicon precursor can be selected from a group consisting of silane (SiH₄), disilane (Si₂H₆), trisilane (Si₃H₈), and tetrasilane (Si₄H₁₀). In further embodiments the silicon precursor can comprise a silicon halide precursor. In such examples the silicon halide precursor can comprise a silicon chloride precursor selected from a group consisting of monochlorosilane (MCS), dichlorosilane (DCS), trichlorosilane (TCS), hexachlorodisilane (HCDS), octachlorotrisilane (OCTS), and silicon tetrachloride (STC). In further embodiments the silicon precursor can comprise a silicon iodide precursor. In such examples the silicon halide precursor can comprise a silicon iodide precursor selected from a group consisting of monoiodosilane, diiodosilane, triiodosilane, tetraiodosilane.

The precursor source 114 component of the gas source assembly 102 may further comprise a germanium source 116. The germanium source 116 may be a structure that provides a flow of a germanium precursor (not shown in FIG. 1) to the chamber arrangement 106 and/or the remote plasma unit 104. The germanium source 116 may be connected to the remote plasma unit 104 via flow controllers (not illustrated in FIG. 1), and may deliver a germanium precursor to the remote plasma unit 104. The germanium source 116 may be further configured to provide a flow of the germanium precursor to the chamber arrangement 106 either directly and/or via the remote plasma unit 104.

In accordance with examples of the disclosure, the germanium source 116 may include a germanium precursor comprising one or more of a germane and/or a germanium halide. In such examples the germanium precursor may comprise a germane, such as germane (GeH₄), digermane (Ge₂H₆), trigermane (Ge₃H₈), or germylsilane (GeH₆Si). In further examples the germanium precursor may comprise a germanium halide such as GeCl₄, GeCl₂, and GeCl₂H₂.

In some embodiments the precursor source 114 may include additional precursors, such as, but not limited to, arsenic precursors, phosphorous precursors, tin precursors, and carbon precursors.

The dopant source 126 may be a structure that provides a flow of a dopant precursor (not shown in FIG. 1) to the chamber arrangement 106 and/or the remote plasma unit 104. The dopant source 126 may be connected to the remote plasma unit 104 via flow controllers, and may deliver a dopant precursor to the remote plasma unit 104. The dopant source 126 may be further configured to provide a flow of the dopant precursor to the chamber arrangement 106 either directly and/or via the remote plasma unit 104.

In some embodiment the dopant precursor may include phosphorous (P). It is also contemplated that the dopant precursor may include boron (B) and/or arsenic (As) and remain within the scope of the present disclosure. In some examples the dopant precursor may include a P-dopant high-order precursor such as diborane (B₂H₆). The dopant precursor gas may include an N-dopant high-order precursor such as phosphine (PH₃) and arsine (AsH₃). The remote plasma unit 104 may decompose at least a portion of the dopant precursor to generate a decomposed dopant precursor. A mixture of the dopant precursor and the decomposed dopant precursor may flow into the chamber arrangement 106 from the remote plasma unit 104.

The carrier source may be a structure that provides a flow of carrier gas to the remote plasma unit 104, and may be additionally configured to provide a flow of the carrier gas to the chamber arrangement 106. The carrier gas may be configured to carry one or more precursors such as the silicon precursor, the germanium precursor, the plasma generated reactant generated by a decomposed precursor from the remote plasma unit 104, and/or the dopant precursor into the chamber arrangement 106. Examples of suitable purge/carrier gases may include hydrogen (H₂) gas, nitrogen (N₂) gas, inert gases such as argon (Ar) gas or helium (He) gas, and mixtures thereof.

The etchant source 128 may be a structure that provides an etchant gas, such as a halide-containing compound, and is configured to provide a flow of the halide-containing compound to the chamber arrangement 106 directly and/or via the remote plasma unit 104. In some embodiments, the halide-containing compound may be co-flowed with a precursor into the remote plasma unit 104. The halide-containing compound may be flowed independently from the precursor, such as to provide a purge and/or to remove condensate from within the remote plasma unit 104 or the chamber arrangement 106. The halide-containing material may be co-flowed with the carrier gas. Examples of suitable halides include chlorine (Cl), e.g., chlorine (Cl₂) gas and hydrochloric (HCl) acid, as well as fluorine (F), e.g., fluorine (F₂) gas, nitrogen trifluoride (NF₃), and hydrofluoric (HF) acid.

In accordance with examples of the disclosure, the remote plasma unit 104 is positioned between and fluidly connected to the gas source assembly 102 and the chamber arrangement 106. In such examples the remote plasma unit 104 is configured to create a plasma generated reactant from one or more of the precursor/gases (e.g., vapor phase reactants) supplied from the gas source assembly 102. In some embodiments the remote plasma unit 104 is configured to create a plasma generated reactant from one or more of the precursors supplied from the precursor source 114.

The remote plasma unit 104 can include a precursor inlet 132 fluidly connected to the process gas output 112 of the gas source assembly 102. The precursor inlet 132 can be supplied with one or more of the process gases as described above (e.g., a silicon precursor, a germanium precursor, a dopant precursor, a carrier gas, and an etchant gas). In some embodiments the precursor source 114 can supply a second vapor phase reactant comprising a silicon precursor to the precursor inlet 132 of the remote plasma unit 104. In such embodiments the precursor source 114 comprises a silicon precursor (i.e., from the silicon source) in fluid communication with the precursor inlet 132 of the remote plasma unit 104. The remote plasma unit 104 can include a plasma outlet 134 which is coupled to and in fluid communication with the chamber arrangement 106. In some embodiments the plasma outlet 134 is coupled to a second inlet 122 of the chamber body 118 of chamber arrangement 106. In particular examples the second vapor phase reactant supplied to the precursor inlet 132 of the remote plasma unit 104 comprises a silicon precursor. In such examples the plasma generated reactant output from the plasma outlet 134 of the remote plasma unit 104 comprises a plurality of energetic silicon species, such as, but not limited to, silicon-containing radicals, silicon-containing metastables, and silicon ions.

In accordance with examples of the disclosure, the remote plasma unit 104 may comprise an inductively coupled plasma source or a microwave plasma source. In particular examples where the remote plasma unit 104 comprises an inductively coupled plasma source (an ICP source), the ICP source may include a precursor conduit (not illustrated) connected to the precursor inlet 132, and a coil (not illustrated) extending about the precursor conduit, and a voltage source electrically connected to the coil and configured to flow a decomposition current through the coil. The coil may be spaced apart from the chamber arrangement 106, for example to prevent the remote plasma unit 104 from disrupting the heating of the chamber, as described in more detail below.

In accordance with examples of the disclosure, the remote plasma unit 104 can comprise a microwave plasma source. In such examples the microwave plasma source can include a precursor conduit (not illustrated) connected to the precursor inlet 132, and a microwave source (not illustrated) configured to generate a microwave to decompose at least a portion of the second vapor phase reactant (e.g., a silicon precursor) provided to the remote plasma unit 104.

In accordance with examples of the disclosure, the remote plasma unit 104 can be configured to generate a plasma generated reactant by the decomposition of a second vapor phase reactant, such as a silicon precursor, for example. The remote plasma unit 104 may connect with the precursor inlet 132 that is coupled to the chamber arrangement 106 via the second inlet 122. In some embodiments, the remote plasma unit 104 may be configured to decompose at least a portion of a silicon precursor provided to the remote plasma unit 104. The remote plasma unit 104 may decompose between about 0.001% and about 90% of the silicon precursor provided to the remote plasma unit 104. For example, between about 0.001% and about 10%, or between about 10% and about 20%, or between about 20% and about 50%, or between about 50% and about 70%, or between about 70% and about 90% of the silicon precursor may be decomposed by the remote plasma unit 104 prior to admission to the chamber arrangement 106. During deposition, an epitaxial material layer comprising silicon may be deposited onto the substrate using a decomposition product generated from the silicon precursor.

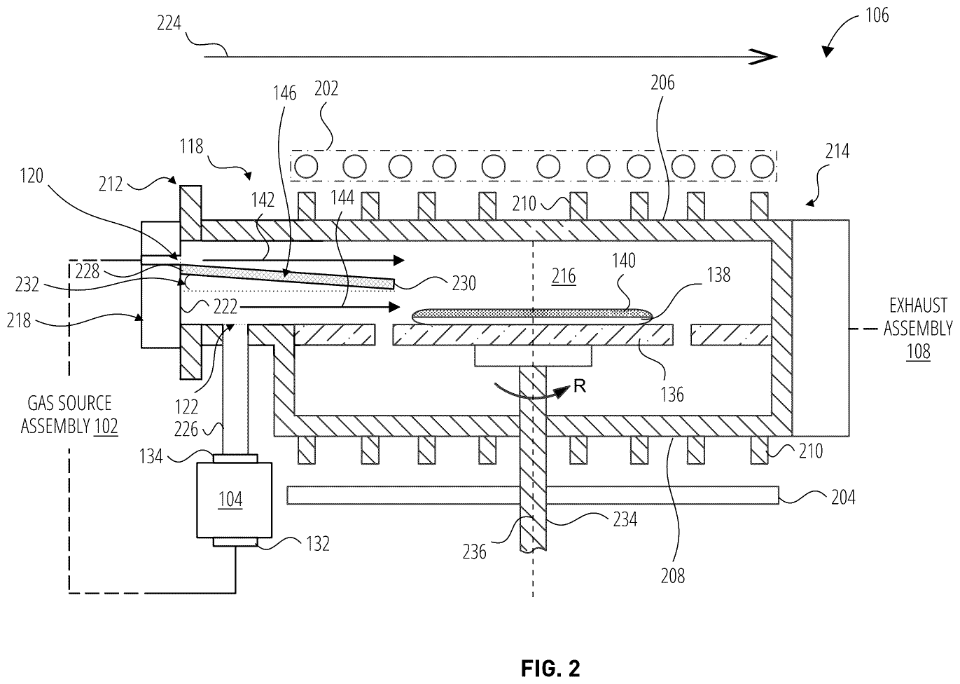

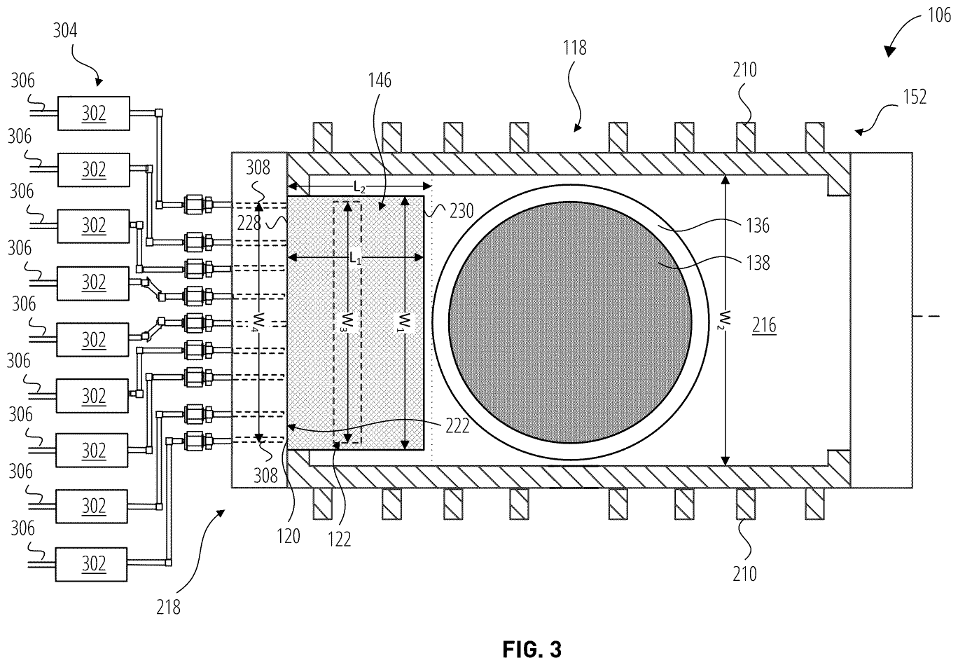

In various embodiments semiconductor processing system 100 of FIG. 1 includes a chamber arrangement 106. In such embodiments the chamber arrangement 106 includes a chamber body 118, as described in greater detail below with reference to FIG. 2 and FIG. 3. The chamber arrangement 106 can further include a substrate support 136 disposed within the interior of the chamber body 118. In some embodiments the substrate support 136 is configured to support a substrate 138 within the interior of the chamber body 118. The chamber arrangement 106 may further comprise a first inlet 120 coupled to the chamber body 118. In such embodiments the first inlet 120 can be in fluid communication with the gas source assembly 102 and be configured for introducing a first vapor phase reactant into the chamber body 118. For example, the flow of the first vapor phase reactant from the first inlet 120 into the interior of the chamber body 118 is illustrated in FIG. 1 by first reactant flow 142. The chamber arrangement 106 may comprise a second inlet 122 coupled to the chamber body 118. In such embodiments the second inlet 122 is separated from the first inlet 120. In some embodiments the second inlet 122 is configured for separately introducing a plasma generated reactant into the chamber body 118. For example, the flow of the plasma generated reactant from the second inlet 122 into the interior of the chamber body 118 is illustrated in FIG. 1 by plasma reactant flow 144.

In various embodiment the semiconductor processing system 100 of FIG. 1 includes an isolating member 146. In such embodiments the isolating member 146 can be positioned between the first inlet 120 and the second inlet 122. The isolating member 146 can be configured to isolate the first vapor phase reactant (as indicated by first reactant flow 142) from the plasma generated reactant (as indicted by plasma reactant flow 144) until the first vapor phase reactant and the plasma generated reactant are proximate to, adjacent to, or in contact with the substrate support 136, as described in detail below.

Semiconductor processing system 100 can also include an exhaust assembly 108. The exhaust assembly 108 may be configured to evacuate the chamber arrangement 106 and may include one or more vacuum pumps 148 and/or an abatement system 150. The vacuum pumps 148 may be connected to the chamber arrangement 106 and configured to control the pressure within the chamber arrangement 106. The abatement system 150 may be connected to the one or more vacuum pumps 148 and be configured to process the flow of residual precursor and/or reaction products issued from the chamber arrangement 106. In some embodiments, the exhaust assembly 108 may be configured to maintain environmental conditions within the chamber arrangement 106 suitable for atmospheric deposition operations, such as pressures between about 600 torr and about 760 torr, such as during the deposition of epitaxial material layers on substrate 138, for example. In some embodiments, the exhaust assembly 108 may be configured to maintain environmental conditions within the chamber body 118 suitable for reduced pressure deposition operations, such as pressures between about 0.01 Torr and about 600 Torr, such as during the deposition of epitaxial on substrate 138 using reduced pressure techniques.

The semiconductor processing system 100 may further comprise a controller 110 including a processor and memory having instructions recorded on the memory that, when read by the processor, cause the processor to perform processes for depositing a material layer 140 on the substrate 138, as described in detail below.

In accordance with examples of the disclosure, FIG. 2 and FIG. 3 schematically illustrate an exemplary chamber arrangement 106 of the present disclosure in greater detail. For example, FIG. 2 illustrates a cross-sectional view of the exemplary chamber arrangement 106 and FIG. 3 illustrates a plan view of the exemplary chamber arrangement 106, and the following description will refer to both FIG. 2 and FIG. 3.

In accordance with examples of the disclosure, the chamber arrangement 106 may comprise a cross flow, cold wall epitaxial reaction chamber. The chamber arrangement 106 may include a chamber body 118 and a substrate support 136. The chamber arrangement 106 may also include an upper heater element array 202 and a lower heater element array 204, as illustrated in FIG. 2. Although a specific arrangement is shown and described herein, it is to be understood and appreciated that the chamber arrangement 106 may include other elements and/or omit elements shown and described herein and remain within the scope of the present disclosure.

In accordance with examples of the disclosure, chamber arrangement 106 includes a chamber body 118. The chamber body 118 can include an upper wall 206, and a lower wall 208. The upper wall 206 and the lower wall 208 extend longitudinally between an injection end 212 and a longitudinally opposite exhaust end 214, at least partially defining a chamber interior 216. In addition, the lower wall 208 is below and parallel to the upper wall 206. In certain examples, the chamber body 118 may be formed from a ceramic material such as sapphire or quartz. The chamber body 118 may include a plurality of external ribs 210. The plurality of external ribs 210 may extend laterally about an exterior of the chamber body 118 and be longitudinally spaced between the injection end 212 and the exhaust end 152 of the chamber body 118. It is also contemplated that, in accordance with certain examples, the chamber body 118 may include no ribs.

In accordance with examples of the disclosure, the chamber body 118 includes a first inlet 120 coupled to the chamber body 118. In such examples the first inlet 120 can be configured for receiving a first vapor phase reactant (supplied from the gas source assembly 102 of FIG. 1) and in turn injecting the first vapor phase reactant into the chamber interior 216 of the chamber body 118. For example, the flow of the first vapor phase reactant, injected from the first inlet 120 into the chamber interior 216 of the chamber body 118 is illustrated by exemplary first reactant flow 142.

In some embodiments the first inlet 120 comprises an injection flange 218 coupled to the injection end 212 of the chamber body 118. In such embodiments the injection flange 218 may comprise a front face 222 which is coupled with the injection end 212 of the chamber body. In some embodiments the injection flange 218 includes a plurality of injection ports (as illustrated by exemplary injection ports 308 in FIG. 3) disposed in a front face 222 of the injection flange 218. In various examples the injection flange 218 further comprises a plurality of flow controllers 302 which can be configured to control a flow of the first vapor phase reactant from the gas source assembly 102 of FIG. 1, to the plurality of injection ports 308 and therethrough to the chamber interior 216 of the chamber body 118.

In accordance with examples of the disclosure, injection flange 218 can comprise a gas distribution assembly 304 (as illustrated in FIG. 3) comprising one or more (e.g., a plurality) of precursor gas lines 306 which can be coupled to the gas source assembly 102 of FIG. 1. In accordance with examples of the disclosure, each one of the plurality of precursor gas lines 306 can be coupled to a flow controller 302. In various embodiments each one of the plurality of the precursor gas lines 306 can be coupled to a flow controller 302. The flow controllers 302 allow independent control of a flow (e.g., a flow rate) of respective gases to injection ports in the front face 222 of the injection flange 218. The flow controllers 302 can include any suitable automatic or manual valve that can control a flow rate of gas to a respective gas channel disposed within the injection flange 218. Although the injection flange 218 is illustrated in FIG. 3 as including nine (9) precursor gas line 306, with nine (9) corresponding flow controller 302, and nine (9) injection ports, the injection flange 218 can include any suitable number of injection ports (and associated precursor gas lines and flow controllers). In some embodiments the injection flange 218 can comprise between 1 and 10 injection ports 220 fed from between 1 and 10 precursor gas lines 306 (via corresponding flow controllers 302). In some embodiments the injection flange 218 can comprise less than 10 injections ports and corresponding precursor lines and flow controllers, less than 8 injection ports and corresponding precursor lines and flow controllers, less than 5 injection ports and corresponding precursor lines and flow controllers, or less than 3 injection ports and corresponding precursor lines and flow controllers.

In accordance with examples of the disclosure, the chamber body 118 includes a second inlet 122 coupled to the chamber body. For example, the second inlet 122 can be configured for introducing a plasma generated reactant into the chamber interior 216 of the chamber body 118.

In accordance with examples of the disclosure and with reference to FIG. 2 and FIG. 3, the second inlet 122 can be separate from the first inlet 120. In such examples the second inlet 122 can be physically separated from the first inlet 120. In some embodiments the second inlet 122 can be vertically separated from the first inlet by positioning the second inlet 122 below the first inlet 120. In some embodiments the second inlet 122 can be vertically separated from the first inlet 120 by positioning the second inlet 122 above the first inlet 120 (not illustrated). In some embodiments the second inlet 122 can be both vertically and horizontally separated from the first inlet 120, as illustrated in FIG. 2. As used herein, a horizontal direction (or horizontal distance) may refer to a direction/distance parallel to the longitudinal orientation (as indicated by arrow 224) of the chamber body 118 and a vertical direction (or vertical distance) may refer to a distance/direction perpendicular to the longitudinal orientation of the chamber body 118. In some embodiments the second inlet 122 is vertically separated from the first inlet 120. In some embodiments the second inlet 122 is both vertically separated from the first inlet 120 and horizontally separated from the first inlet 120.

In accordance with examples of the disclosure, the second inlet 122 can be coupled to the plasma outlet 134 of the remote plasma unit 104. In some embodiments the plasma outlet 134 of the remote plasma unit 104 is directly coupled to the second inlet 122. In such examples the second inlet 122 is coupled to the chamber interior 216 and is configured for introducing a plasma generated reactant into the chamber interior 216, as illustrated in FIG. 2 by exemplary plasma reactant flow 144.

In accordance with examples of the disclosure, the second inlet 122 can be disposed in the lower wall 208 of the chamber body 118. In such examples the second inlet 122 may comprise a channel opening created within the lower wall 208 of the chamber body. For example, the plasma outlet 134 of the remote plasma unit 104 can be coupled either directly, or via a plasma feed tube 226, to the second inlet 122 disposed in the lower wall 208 of the chamber body 118. In some embodiments the second inlet 122 is sized and arranged to introduce the plasma generated reactant into the chamber interior 216 without significant loss of the plasma generated reactant.

In accordance with examples of the disclosure, the second inlet 122 can be positioned between the injection flange 218 and the substrate support 136. As illustrated in both FIG. 2 and FIG. 3, an exemplary second inlet 122 is positioned horizontally (i.e., along the longitudinal orientation of the chamber body longitudinal axis 224) between the injection flange 218 and the substrate support 136.

In accordance with examples of the disclosure, an isolating member 146 can be disposed within the chamber interior 216, i.e., an in-situ isolating member. In such examples the isolating member 146 can be employed to maintain a physical separation between the first vapor phase reactant introduced into the chamber interior 216 from the first inlet 120 (as indicted by first reactant flow 142) and a plasma generated reactant introduced into the second inlet 122 (as indicted by plasma reactant flow 144). For example, the isolating member 146 can be configured to isolate the first vapor phase reactant (e.g., 142) from the plasma generated reactant (e.g., 144) until the first vapor phase reactant and the plasma generated reactant are proximate to, adjacent to, or in contact with the substrate support 136 and/or the substrate.

In some embodiments the isolating member 146 can comprise an opaque material. In some embodiments the isolating member 146 can be fabricated from silicon carbide (SiC). In some embodiments the isolating member 146 can be fabricated from a quartz material coated with silicon carbide. In some embodiments the isolating member 146 can comprise a transparent material. In such embodiments the isolating member 146 can be fabricated from a quartz material.

In some embodiments the isolating member 146 can be integrated with the second inlet 122. In some embodiments the isolating member 146 can be integrated with injection end 212 of the chamber body 118. In some embodiments the isolating member 146 can be integrated with injection flange 218.

In some embodiments the isolating member 146 can comprise a planar plate. In some embodiments the isolating member 146 comprises a rectangular planar plate. In such embodiments the isolating member can have a width W₁ and a length L₁, as illustrated in FIG. 3. In some embodiments the width W₁ of the isolating member 146 can be less than the width W₂ of the chamber interior 216. In some embodiments the width W₁ of the isolating member 146 can be less than the diameter of the substrate support 136. In some embodiments the width W₁ of the isolating member 146 can be greater than the diameter of the substrate support 136. In some embodiments the width W₁ of the isolating member 146 can be greater than the diameter of a substrate 138 positioned on the substrate support 136. In some embodiments the width W₁ of the isolating member 146 can be less than the diameter of a substrate 138 positioned on the substrate support 136.

In some embodiments the width W₁ of the isolating member 146 can be greater than the width W₃ of the second inlet 122, as illustrated in FIG. 3. In some embodiments the width W₁ of the isolating member 146 can be greater than the width W₄ of the first inlet 120. For example, the width W₁ of the isolating member 146 can be greater than the maximum width W₄ between the plurality of injection port 220 of the injection flange 218.

In some embodiments the length L₁ of the isolating member 146 is less than the horizontal distance L₄ between the first inlet 120 (e.g., from the front face 222 of the injection flange 218) to an outer perimeter of the substrate support 136 (as illustrated in FIG. 3). In some embodiments the length L₁ of the isolating member 146 is greater than the horizontal distance L₄ between the first inlet 120 (e.g., from the front face 222 of the injection flange 218) to an outer perimeter of the substrate support 136.

In some embodiments the isolating member 146 may comprise alternative geometries, shapes, and arrangements to those described above.

In some embodiments the isolating member 146 can be positioned between the first inlet 120 and the second inlet 122. In such embodiments the isolating member 146 can extend into the chamber interior 216 from the injection flange 218 toward the substrate 138.

In accordance with examples of the disclosure, a first end 228 of the isolating member 146 can be positioned proximate to the first inlet 120 (e.g., proximate to the plurality of injection ports injection ports 308 of the injection flange 218). In some embodiments the first end 228 of the isolating member 146 can be positioned adjacent to the first inlet 120 (e.g., adjacent to the plurality of injection ports 308). In some embodiments the first end of the isolating member 146 contacts the first inlet 120. In some embodiments the first end 228 of the isolating member 146 contacts the front face 222 of the injection flange 218.

In some embodiments the first end 228 of the isolating member 146 can be positioned below the first inlet 120 (e.g., below the plurality of injection ports 220 of the injection flange 218). In some embodiments the first end 228 of the isolating member 146 can be positioned below the first inlet 120 (e.g., adjacent to the plurality of injection ports 220). In some embodiments the first end of the isolating member 146 contacts the first inlet 120 below the point of gas injection. In some embodiments the first end 228 of the isolating member 146 contacts the front face 222 of the injection flange 218 below the plurality of injection ports 220.

In accordance with examples of the disclosure, a second end 230 of the isolating member 146, distal from the first end 228, can be positioned proximate to the substrate support 136. In such embodiments the isolating member 146 can extend from the injection end 212 of the chamber body 118 into the chamber interior 216 towards the substrate support 136. In some embodiments the second end 230 of the isolating member 146 can be positioned adjacent to the substrate support 136. In some embodiments the second end 230 of the isolating member 146 can be positioned adjacent to the substrate 138.

In some embodiments the second end 230 of the isolating member is positioned horizontally proximate to the substrate support (i.e., the second end is proximate to the substrate support 136 in the horizontal direction parallel with the longitudinal orientation 224 of the chamber body 118). In some embodiments the second end 230 of the isolating member is positioned horizontally adjacent to the substrate support (i.e., the second end is adjacent to the substrate support 136 in the horizontal direction parallel with the longitudinal orientation of the chamber body 118). In some embodiments the second end 230 of the isolating member is positioned horizontally adjacent to the substrate 138 (i.e., the second end is adjacent to the substrate 138 in the horizontal direction parallel with the longitudinal orientation of the chamber body 118).

In some embodiments the second end 230 of the isolating member 146 is positioned vertically proximate to the substrate support 136 (i.e., a lower surface of the second end 230 of the isolating member 146 is proximate to an upper surface of the substrate support 136 in the vertical direction perpendicular with the longitudinal orientation 224 of the chamber body 118). In some embodiments a lower surface of the second end 230 of the isolating member 146 is positioned vertically adjacent to an upper surface of the substrate support 136 (i.e., a lower surface of the second end 230 of the isolating member 146 is adjacent to the substrate support 136 in the vertical direction perpendicular with the longitudinal orientation of the chamber body 118). In some embodiments a lower surface of the second end 230 of the isolating member 146 is positioned vertically adjacent to an upper surface of the substrate 138 (i.e., a lower surface of the second end 230 of the isolating member 146 is adjacent to the substrate 138 in the vertical direction perpendicular with the longitudinal orientation of the chamber body 118).

In some embodiments the second end 230 of the isolating member 146 is positioned both horizontally and vertically proximate to the substrate support 136. In some embodiments the second end 230 of the isolating member 146 is positioned both horizontally and vertically adjacent to the substrate support 136.

In some embodiments the isolating member 146 can extend into the chamber interior 216 from the injection flange 218 toward the substrate 138 such that the isolating member is parallel, or substantially parallel, with the longitudinal orientation 224 of the chamber body 118. In some embodiments the isolating member 146 can extend into the chamber interior 216 from the injection flange 218 toward the substrate support 136 such that the isolating member is non-parallel with the longitudinal orientation of the chamber body 118. In some embodiments the isolating member 146 can extend into the chamber interior 216 from the injection flange 218 at an angle sloped toward the substrate support. In such embodiments the isolating member 146 can slope downward from the injection flange 218 down toward the substrate 138.

In some embodiments the second end 230 of the isolating member 146 can be positioned above the first end 228 of the isolating member 146 (not illustrated). In some embodiments the second end 230 of the isolating member 146 can be positioned below the first end 228 of the isolating member 146, as illustrated in FIG. 2. In such embodiments the angle between the isolating member 146 and the longitudinal orientation of the chamber body (i.e., angle 232 of FIG. 2) can be greater than 1 degree, greater than 5 degrees, greater than 10 degrees, greater than 20 degrees, greater than 30 degrees, greater than 45 degrees, or between 1 degree and 89 degrees, or between 1 degree and 45 degrees, or between 1 degree and 20 degrees.

As illustrated in FIG. 2 and FIG. 3 the substrate support 136 can be positioned between the injection end 212 and the exhaust end 152 of the chamber body 118. The substrate support 136 can comprise a shaft member 234 arranged within the chamber body 118 and configured for rotation about a rotation axis 236 within the interior of the chamber body 118. The substrate support 136 may be formed from an opaque material, such as silicon carbide or a bulk graphite material.

The upper heater element array 202 may be configured to heat the substrate 138 and/or the material layer 140 during deposition onto the substrate 138 by radiantly communicating heat into the interior of the chamber body 118. The upper heater element array 202 may include a plurality of upper linear lamps supported above the chamber body 118 and optically coupled to the substrate support 136 by the material forming the chamber body, e.g., a quartz material. The lower heater element array 204 may be similar to the upper heater element array 202 and may also be configured to heat the substrate 138 and/or the material layer 140 during deposition onto the substrate 138. The lower heater element array 204 may include a plurality of lower linear lamps supported below the chamber body 118 and optically coupled to the substrate support 136 by the material forming the chamber body 118.

In certain examples the remote plasma unit 104 may be one of a plurality of remote plasma units coupling a gas manifold header, and the gas source assembly 102 therethrough, to the chamber arrangement 106 via intermediate flow controllers. In such examples each of the plurality of remote plasma units may couple the gas manifold header through a singular mass flow controller (MFC) to the chamber arrangement 106 to provide tunability to the flow of radicals into the chamber arrangement. Examples of suitable gas manifold headers and MFC arrangements include those shown and described in U.S. Pat. No. 11,053,591 to Ma et al, issued on Jul. 6, 2021, the contents of which are incorporated herein by reference in its entirety.

The various embodiments provided may include a semiconductor processing system 100 comprising a controller 110 communicatively coupled with various other components of the semiconductor processing systems 100 (see FIG. 1) (including the associated chamber arrangements illustrated in FIG. 2 and FIG. 3) and may be configured to control their operations. For example, the controller 110 may control a remote plasma unit, such as by controlling one or more of plasma power and ignition. The controller 110 may control the flow of a first vapor phase reactant into the chamber interior of a chamber body from a first inlet. The controller 110 may control the flow of a plasma generated reactant into the chamber interior of chamber body from a second inlet separate from the first inlet. The controller 110 may control the seating of the substrate on the substrate support, heating of the substrate, and/or flow of the precursor to the remote plasma unit and the injection flange.

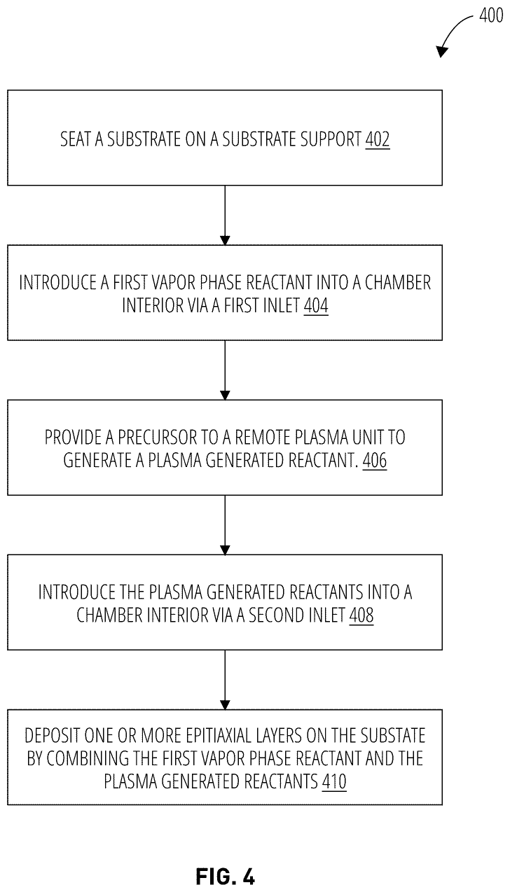

FIG. 4 illustrates an example process flow 400 describing a process for a material layer deposition method using a semiconductor processing system according to one or more aspects of the disclosure.

In accordance with examples of the disclosure, at step 402 the controller (e.g., controller 110 of FIG. 1) of a semiconductor processing system may seat a substrate on the substrate support, such as the semiconductor processing system 100, substrate 138 and substrate support 136, as described with reference to FIG. 1.

In accordance with examples of the disclosure, at step 404 a first vapor phase reactant may be provided to a first inlet coupled to a chamber body of a chamber arrangement. In such examples, the first inlet is configured for introducing the first vapor phase reactant into the chamber interior of the chamber body. In some embodiments the first vapor phase reactant comprises one or more germanium precursors. In some embodiments the first vapor phase reactant does not comprise a silicon precursor. In some embodiments the first vapor phase reactant comprises one or more germanium precursors and does not comprise a silicon precursor. In some embodiments the first vapor phase reactant comprises one or more germanium precursors and one or more of a dopant gas, an etchant gas, a carrier gas, and does not comprise a silicon precursor. In some embodiments the first vapor phase reactant can comprise one or more germanium precursors, and one or more of silicon precursors, a dopant gas, an etchant gas, and a carrier gas.

In accordance with examples of the disclosure, at the step 406 a precursor may be provided to the remote plasma unit. For example, the controller may control a precursor source or precursor gas(es) to provide the precursor to the remote plasma unit. The remote plasma unit may include an inductively coupled remote plasma unit or a microwave remote plasma unit. The inductively coupled remote plasma unit may include a precursor inlet, and a precursor conduit connected to the precursor inlet. In some embodiments, the precursor may comprise a silicon precursor which may flow from the precursor source to the remote plasma unit via the precursor inlet. The inductively coupled remote plasma unit may further include a coil extending about the precursor conduit, and a voltage source electrically connected to the coil and configured to flow a decomposition current through the coil. The coil may be spaced apart from the chamber body to prevent disruption to the heater element array in the chamber body and damaging the quartz body.

In some examples, the precursor gases provided to the remote plasma unit may include a silicon precursor, such as any one or more of the silicon precursors described above. In some examples, the precursor gases may include one or more germanium precursors, dopant precursors, an etchant gas, and carrier gas, as described above. In particular examples, the precursor gas provided to the remote plasma unit is a silicon precursor. In particular examples, the precursor gas provided to the remote plasma unit consists essentially of a silicon precursor. In particular examples, the precursor gas provided to the remote plasma unit consists of a silicon precursor. In particular examples, the precursor gas provided to the remote plasma unit is a silicon precursor and a carrier gas. In particular examples, the precursor gas provided to the remote plasma unit consists essentially of a silicon precursor and a carrier gas. In particular examples, the precursor gas provided to the remote plasma unit consists of a silicon precursor and a carrier gas.

In some embodiments at least a portion of the precursor (e.g., a silicon precursor) may be decomposed using the remote plasma unit to generate plasma generated reactants. In some embodiments, the remote plasma unit may decompose at least a portion of a silicon precursor to generate a decomposition product comprising the plasma generated reactants. For example, any amount between about 0.001% and about 90% of the silicon precursor provided to the remote plasma source may be decomposed to create the plasma generated reactants.

As the precursor (e.g., a silicon precursor) flows through the conductive coil of the remote plasma unit, a plasma may be generated by breaking the precursor molecules into different forms, such as a form with free radicals. A decomposition product carrying free radicals may be more active and more likely to participate in the chemical reactions on the surface of the substrate. The un-decomposed form of the precursor may be less active and less likely to participate in the chemical reactions on the surface of the wafer. For example, a silicon precursor SiH₄ may be partially decomposed to a mixture of SiHx(−) and SiH₄. The mixture of the silicon precursor (e.g., SiH₄) and the decomposition product (e.g., SiHx(−) or other silicon-containing radical) may flow into the chamber interior of a chamber body.

In some examples, a purge/carrier gas source may be provided to the remote plasma unit to carry one or more of the precursors (e.g., a silicon precursor), the decomposition product (e.g., the plasma generated reactants), and/or the dopant source to flow into the chamber body. Examples of purge/carrier gases may include hydrogen (H₂) gas, nitrogen (N₂) gas, inert gases such as argon (Ar) gas or helium (He) gas, and mixtures thereof.

In some examples, the controller may be communicatively coupled with the remote plasma unit to control the decomposition of the precursor (e.g., a silicon precursor). For example, the controller may tune the frequency of a radio frequency (RF) signal applied to the remote plasma unit to induce the generation of the plasma. The controller may determine a frequency range that may promote the decomposition of the precursor (e.g., a silicon precursor) and in turn, the wafer growth rate in the chamber body. The controller may tune the plasma generating temperature applied to the remote plasma unit to induce the generation of the plasma. The controller may determine a temperature range that may promote the decomposition of the precursor (e.g., a silicon precursor) and in turn, the growth rate of a material layer epitaxially deposited on the substrate. Note that the plasma generating temperature may still be relatively lower than the temperature applied to the processing chamber in the conventional system to decompose the precursor in the chamber body.

In accordance with examples of the disclosure, at step 408 the plasma generated reactant may be provided to a second inlet coupled to a chamber body of a chamber arrangement. In such examples, the second inlet is configured for introducing the plasma generated reactants into the chamber interior of the chamber body. In some embodiments the plasma generated reactants comprise a plurality of energetic silicon species, such as, but not limited to, silicon-containing radicals, silicon-containing metastables, and silicon ions.

In accordance with examples of the disclosure, at step 410 one or more epitaxial layers can be epitaxial deposited on the substrate by combining the first vapor phase reactant with the plasma generated reactants. For example, depositing the one or more epitaxial layers may comprise rotating the substrate about a rotation axis and flowing both the first vapor phase reactant and the decomposition product (i.e., the plasma generated reactant) longitudinally through the chamber interior. In such examples the first vapor phase reactant and the plasma generated reactants can be isolated from one another until proximate to, adjacent to, or in contact with the substrate support by employing an isolating member disposed between the first inlet and the second inlet. The controller may be communicatively coupled with the chamber body to control the deposition process. The decomposition product may flow from the remote plasma unit into the chamber interior of the chamber body via the second inlet.

In accordance with examples of the disclosure, during step 410, one or more epitaxial layers may be deposited onto the substrate using the decomposition product generated from the silicon precursor (i.e., the plasma generated reactants) and the first vapor phase reactant. The heating of the substrate during deposition of the silicon precursor by the heater element array may be limited by the decomposition product. Given that the decomposition product may be more reactive and more likely to participate in the chemical reaction on the surface of the substrate, an isothermal and/or lower temperature regime may be applied to the chamber body to achieve an optimal growth rate and/or throughput of the two or more epitaxial material layers.

The various embodiments provided include methods for depositing a super-lattice structure on a substrate employing the semiconductor processing systems and arrangements described above.

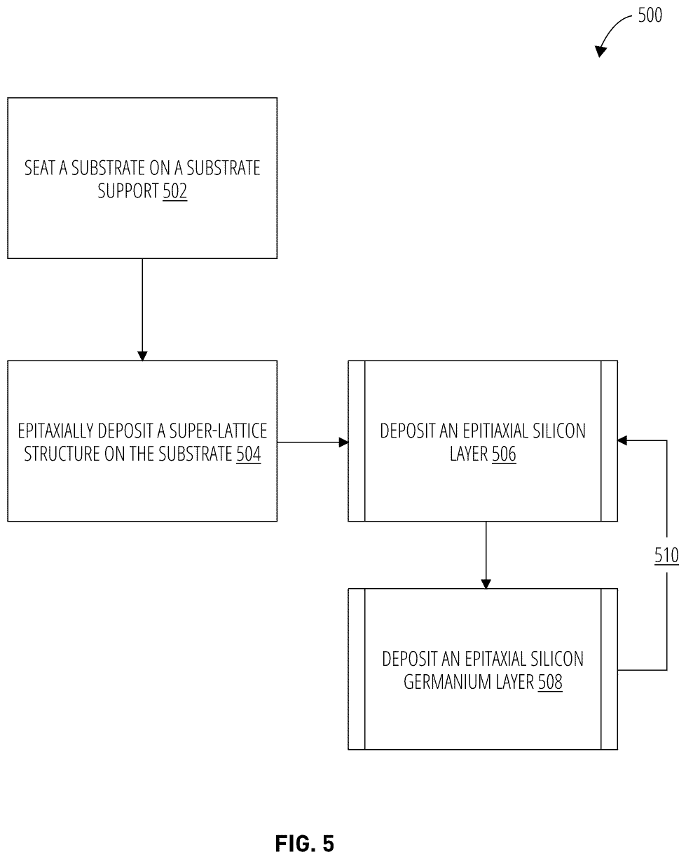

In accordance with examples of the disclosure, the process flow 500 of FIG. 5 illustrates an exemplary process for forming a super-lattice structure on a substrate.

In accordance with examples of the disclosure, the process flow 500 can include a step 502 which comprising, at a chamber body having an upper wall and a lower wall, wherein the upper wall extends longitudinally between an injection end and an longitudinally opposite exhaust end, and the lower wall is below and parallel relative to the upper wall, such as described previously above.

In accordance with examples of the disclosure, the process flow 500 can include an epitaxial deposition step 504 which comprising epitaxially depositing a super-lattice structure on the substrate supported on a substrate support disposed within an interior of the chamber body between the injection end and the exhaust end. In such examples, the super-lattice structure may comprise two or more repeated unit bilayers. For example, each unit bilayer (constituting the super-lattice structure) can comprise an epitaxial silicon layer and an adjoining epitaxial silicon germanium layer.

In various embodiments depositing each unit bilayer (i.e., Si/SiGe) of the super-lattice structure can comprise performing two or more epitaxial deposition super cycles (as indicated by cycle loop 510). In some embodiments each deposition super cycle can comprise depositing an epitaxial silicon layer by performing a first epitaxial deposition process 506 and depositing an epitaxial silicon germanium layer by performing a second epitaxial deposition process 508. In some embodiments the epitaxial deposition super cycle (as indicted by cycle loop 510) can be repeated to deposit further bilayers (e.g., Si/SiGe) on the substrate. In some embodiments the cycle loop 510 can be repeated 2 or more times, 5 or more times, 10 or more times, 15 or more times, 20 or more times, 25 or more times, 30 or more times, 40 or more times, 60 or more times, 80 or more times, 100 or more times, 200 or more times, 300 or more times, or between 2 and 300 times. In some embodiments the cycle loop 510 may be initiated by the second epitaxial deposition process 508 followed by the first epitaxial deposition process 506. In some embodiments the cycle loop 510 may comprise addition process steps, such as, but not limited, surface cleans, chamber cleans, and the like.

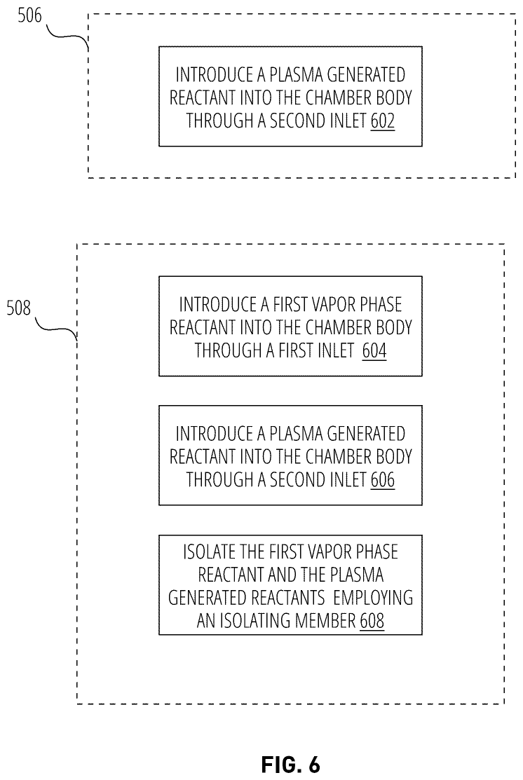

In various embodiments the first epitaxial deposition process 506 may comprise a sub-step 602 for depositing the epitaxial silicon layer, as illustrated in FIG. 6. In some embodiments sub-step 602 comprises introducing a plasma generated reactant into the chamber body through a second inlet coupled to the chamber body and separate from a first inlet. In such embodiments the plasma generated reactant is generated by introducing a second vapor phase reactant comprising a silicon precursor to a remote plasma unit configured for generating the plasma generated reactant.

In various embodiments the second epitaxial deposition process 508 may comprise the sub-steps 604, 606, and 608 as illustrated in FIG. 6. In some embodiments the sub-step 604 comprises introducing a first vapor phase reactant comprising a germanium precursor into the chamber body through the first inlet coupled to the chamber body. In some embodiments the sub-step 606 comprises introducing the plasma generated reactant into the chamber body through the second inlet coupled to the chamber body and separate from the first inlet, wherein the plasma generated reactant is generated by introducing the second vapor phase reactant comprising the silicon precursor to the remote plasma unit configured for generating the plasma generated reactant. In some embodiments the sub-step 608 comprises isolating the first vapor phase reactant and the plasma generated reactants from one another until the first vapor phase reactant and the plasma generated reactant are proximate to, adjacent to, or in contact with the substrate support and/or substrate by employing an isolating member positioned between the first inlet and the second inlet.

In various embodiments epitaxially depositing the super-lattice structure comprises an isothermal epitaxial deposition process. In some embodiments performing two or more epitaxial deposition super cycles (as indicated by cycle loop 510 in FIG. 5) is performed at the same, or substantially the same, deposition temperature (i.e., substrate temperature). In some embodiments the first epitaxial deposition process 506 can be performed at a first substrate temperature and the second epitaxial deposition process 508 can be performed at a second substrate, where the first substrate temperature and the second substrate temperature are the same, or substantially, the same substrate temperature. As used herein, an isothermal epitaxial deposition process can refer to an epitaxial deposition process where the variation in the deposition temperature is less than 5%, less than 4%, less than 3%, less than 2%, less than 1%, or between 1% and 5%. Likewise, when referring to an epitaxial deposition process which comprises a substantially the same substrate temperature, the term “substantially” can refer to a variation in the substrate temperature of less than 5%, less than 4%, less than 3%, less than 2%, less than 1%, or between 1% and 5%.

The ability to deposit a super-lattice structure by isothermal epitaxial deposition process can be enabled by employing both vapor phase reactants and plasma generated reactants for the deposition of the unit bilayer structure comprising an epitaxial silicon layer and an epitaxial silicon germanium layer.

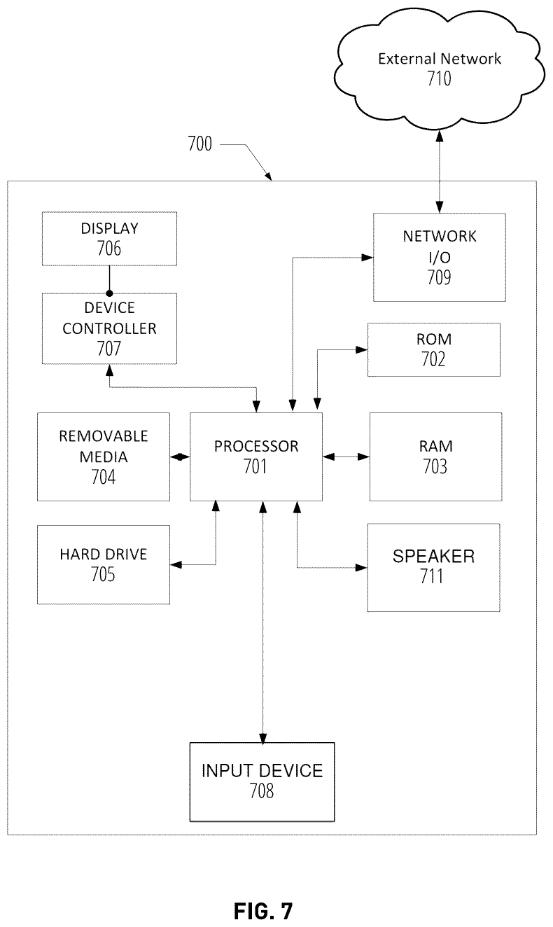

FIG. 7 depicts an example of a computing device that may be used in implementing one or more aspects of the disclosure. The computing device may be a device for controlling the systems (e.g., 100) and performing the processes (e.g., 400 and 500) described herein. For example, one or more devices and components as described herein (e.g., the controller 110) may be implemented with the device shown in FIG. 7.

The term “network” as used herein and depicted in the drawings refers not only to systems in which remote storage devices are coupled together via one or more communication paths, but also to stand-alone devices that may be coupled, from time to time, to such systems that have storage capability. An example system 700 may be used according to one or more illustrative aspects described herein. The system 700 may have a processor 701 for controlling overall operation of the system and its associated components, including read-only memory (ROM) 702, random access memory (RAM) 703, removable media 704, a hard drive 705, a display device 706, a device controller 707, an input device 708, a network input/output (I/O) device 709, and a speaker 711.

The input device 708 may include a mouse, keypad, touch screen, scanner, optical reader, and/or stylus (or other input device(s)) through which a user of the system 700 may provide input. One or more speakers 711 may provide audio output, and the display device 706 may provide textual, audiovisual, and/or graphical output. Software may be stored within the removable media 704 and/or the hard drive 705 to provide instructions to processor 701 for configuring the system 700 into a special purpose computing device in order to perform various functions as described herein. For example, the removable media 704 and/or the hard drive 705 may store software used by the system 700, such as an operating system, application programs, and/or an associated database.

The system 700 may operate in a networked environment supporting connections to one or more remote computers or components, such as the gas source assembly 102, the remote plasma unit 104, the chamber arrangement 106 and exhaust assembly 108, etc. The external network 710 may include a local area network (LAN) and a wide area network (WAN), but may also include other networks. When used in a LAN networking environment, the system 700 may be connected to the LAN through the network I/O 709 (e.g., a network interface or adapter). When used in a WAN networking environment, the system 700 may include a modem or other wide area network interface for establishing communications over the WAN, such as the Internet. It will be appreciated that the network connections shown are illustrative and other means of establishing a communications link between the computers may be used. The system 700 may be a mobile terminal (e.g., a mobile phone, a smartphone, a personal digital assistant (PDA), a laptop computer, etc.) including various other components, such as a battery, speaker, and antennas (not shown).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed:

1. A semiconductor processing system, comprising:
a chamber body having an upper wall and a lower wall, wherein the upper wall extends longitudinally between an injection end and a longitudinally opposite exhaust end, and the lower wall is below and parallel relative to the upper wall;
a substrate support configured to support a substrate and arranged within an interior of the chamber body between the injection end and the exhaust end;
a first inlet coupled to the chamber body and configured for introducing a first vapor phase reactant into the chamber body;
a second inlet coupled to the chamber body and separated from the first inlet; the second inlet configured for introducing a plasma generated reactant into the chamber body;
a remote plasma unit having a plasma outlet coupled to the second inlet and configured to generate the plasma generated reactant by decomposition of a second vapor phase reactant; and
an isolating member positioned between the first inlet and the second inlet and configured to isolate the first vapor phase reactant from the plasma generated reactant until the first vapor phase reactant and plasma generated reactant are proximate to the substrate support.

2. The semiconductor processing system of claim 1, wherein the first inlet comprises an injection flange connected to the injection end of the chamber body.

3. The semiconductor processing system of claim 2, wherein the injection flange comprises a plurality of injection ports disposed in a front face of the injection flange, and a plurality of flow controllers configured to control a flow of the first vapor phase reactant from a precursor source to the plurality of injection ports and therethrough to the interior of the chamber body.

4. The semiconductor processing system of claim 3, wherein the second inlet is positioned between the injection flange and the substrate support.

5. The semiconductor processing system of claim 4, wherein the second inlet is disposed in the lower wall of the chamber body.

6. The semiconductor processing system of claim 5, wherein the isolating member extends into the interior of the chamber body from the injection flange toward the substrate support.

7. The semiconductor processing system of claim 6, wherein the isolating member comprises an opaque material.

8. The semiconductor processing system of claim 7, wherein the isolating member is positioned a vertical distance above the substrate support.

9. The semiconductor processing system of claim 8, wherein the isolating member is angled toward the substrate support.

10. The semiconductor processing system of claim 9, wherein the precursor source includes a silicon precursor in fluid communication with a precursor inlet of the remote plasma unit and the plasma generated reactant comprises a plurality of energetic silicon species.

11. The semiconductor processing system of claim 10, wherein the remote plasma unit comprises an inductively coupled plasma source or a microwave plasma source.

12. The semiconductor processing system of claim 11, further comprising an exhaust flange connected to the exhaust end of the chamber body and a vacuum pump coupled to the exhaust flange and therethrough to the remote plasma unit.

13. The semiconductor processing system of claim 12, wherein the chamber body has a plurality of external ribs extending laterally about an exterior of the chamber body and longitudinally spaced apart from one another between the injection end and the longitudinally opposite the exhaust end of the chamber body.

14. The semiconductor processing system of claim 13, further comprising a heater element array supported outside of the chamber body and optically coupled to the substrate support and the isolating member, the heater element array comprising:
a plurality of lower linear lamps supported below the chamber body and optically coupled to the substrate support and the isolating member by a quartz material forming the chamber body; and
a plurality of upper linear lamps supported above the chamber body and optically coupled to the substrate support and the isolating member by the quartz material forming the chamber body.

15. The semiconductor processing system of claim 14, further comprising a controller including a processor and memory having instructions recorded on the memory that, when read by the processor, cause the processor to:
seat the substrate on the substrate support;
provide a germanium precursor to the injection flange;
provide the silicon precursor to the remote plasma unit;
decompose at least a portion of the silicon precursor using the remote plasma unit to generate the plasma generated reactant; and
depositing one or more epitaxial silicon-containing layers onto the substrate by combining the germanium precursor with the plasma generated reactant created using a decomposition product generated from the silicon precursor, wherein depositing the one or more epitaxial silicon-containing layers is an isothermal deposition process.

16. A method for forming a super-lattice structure on a substrate, the method comprising:
at a chamber body having an upper wall and a lower wall, wherein the upper wall extends longitudinally between an injection end and a longitudinally opposite exhaust end, and the lower wall is below and parallel relative to the upper wall;
epitaxially depositing the super-lattice structure on the substrate supported on a substrate support disposed within an interior of the chamber body between the injection end and the exhaust end, wherein the super-lattice structure comprises two or repeated unit bilayers, each unit bilayer comprising an epitaxial silicon layer and an adjoining epitaxial silicon germanium layer; and wherein depositing each unit bilayer of the super-lattice structure comprises performing two or more epitaxial deposition super cycles, each deposition super cycle comprising:
depositing the epitaxial silicon layer by performing a first epitaxial deposition process comprising:
introducing a plasma generated reactant into the chamber body through a second inlet coupled to the chamber body and separate from a first inlet, wherein the plasma generated reactant is generated by introducing a second vapor phase reactant comprising a silicon precursor to a remote plasma unit configured for generating the plasma generated reactant; and
depositing the epitaxial silicon germanium layer on the epitaxial silicon layer by performing a second epitaxial deposition process comprising:
introducing a first vapor phase reactant comprising a germanium precursor into the chamber body through the first inlet coupled to the chamber body;
introducing the plasma generated reactant into the chamber body through the second inlet coupled to the chamber body and separate from the first inlet, wherein the plasma generated reactant is generated by introducing the second vapor phase reactant comprising the silicon precursor to the remote plasma unit configured for generating the plasma generated reactant; and
isolating the first vapor phase reactant and the plasma generated reactant from one another until the first vapor phase reactant and the plasma generated reactant are proximate to the substrate support by employing an isolating member positioned between the first inlet and the second inlet.

17. The method of claim 16, wherein epitaxially depositing the super-lattice structure comprises an isothermal epitaxial deposition process.

18. The method of claim 17, wherein the first inlet comprises an injection flange connected to the injection end of the chamber body, the injection flange comprising a plurality of injection ports disposed in a front face of the injection flange, and a plurality of flow controllers configured to control a flow of the first vapor phase reactant from a precursor source to the plurality of injection ports and therethrough to the interior of the chamber body.

19. The method of claim 18, wherein the second inlet is disposed in the lower wall of the chamber body between the injection flange and the substrate support.

20. The method of claim 19, wherein the isolating member comprises an opaque material.
